(19) United States
(12) Patent Application Publication
(10) Pub. No.: US 2025/0138076 A1
(43) Pub. Date: May 1, 2025

(54) ESTIMATION APPARATUS, ESTIMATION METHOD, AND PROGRAM

(71) Applicant: NIPPON TELEGRAPH AND TELEPHONE CORPORATION, Tokyo (JP)

(72) Inventors: Naoki HANAOKA, Tokyo (JP); Toru TANAKA, Tokyo (JP); Naomichi NAKAMURA, Tokyo (JP); Yuji HIGUCHI, Tokyo (JP)

(21) Appl. No.: 18/836,978

(22) PCT Filed: Mar. 18, 2022
(86) PCT No.: PCT/JP2022/012901

§ 371 Date: Aug. 8, 2024

(51) Int. Cl. G01R 31/08

(52) U.S. Cl. CPC G01R 31/088; G01R 31/086

(57) ABSTRACT

An estimation device for estimating a position of occurrence of an accident on a feeder in a DC power supply system in which a plurality of bases each having a power supply device are connected by the feeder, the estimation device including: an information acquisition unit that acquires information from each base when the accident occurs; and an estimation unit that estimates the position of occurrence of the accident in the feeder by comparing the information between the bases.

### TECHNICAL FIELD

The present invention relates to a technique for estimating the position of occurrence of an accident such as a short circuit.

### BACKGROUND ART

In communication buildings, data centers, or the like, high-voltage DC power supply systems are introduced to reduce power loss of the entire systems and achieve energy saving. In a DC power supply system, power feeding (power distribution) is performed by a high voltage such as 380 V.

In a conventional DC power supply system, power is generally supplied indoors. In an indoor DC power supply system, power is supplied by a cable of approximately 60 m at maximum. The power supply direction is one direction to a load such as an ICT device.

### CITATION LIST

### Non-Patent Literature

Non-Patent Literature 1: IEEJ2021 General Lecture 6-056 “A Study of Short Circuit Protection Method for Outdoor DC Power Supply System”, Hanaoka et al.

### SUMMARY OF INVENTION

### Technical Problem

It is assumed that an outdoor DC power supply system for supplying power by direct current through an outdoor feeder is introduced in the future (for example, Non-Patent Literature 1). Further, it is assumed that a plurality of bases having a power supply converter are connected on an n-to-n basis and bidirectional power supply is performed between the bases.

In an outdoor DC power supply system, there is a case where power is supplied to a load located several km away (for example, 4 km at most). In this case, the impedance (resistance component, inductance component) becomes very large as compared with the conventional indoor DC power supply system.

There is a case where an accident such as a short circuit occurs in a feeder of a DC power supply system. A short circuit means that a positive-side feeder and a negative-side feeder are connected by a small resistance. When a short circuit occurs, a large current flows through the feeder.

In a conventional indoor DC power supply system, a short circuit point can be easily visually confirmed when a short circuit occurs. However, in the outdoor DC power supply system described above, since the distance between the bases (the length of the feeder) is large, when a short circuit occurs, it is difficult to immediately know where the short circuit point is located. This problem is a problem that commonly occurs in case of an accident (including ground fault) on a feeder not limited to a short circuit.

The present invention was made in view of the points described above, and an object thereof is to provide a technique for estimating the position of occurrence of an accident in a feeder of a DC power supply system in which a plurality of bases are connected by the feeder.

### Solution to Problem

According to the disclosed technique, provided is an estimation device for estimating a position of occurrence of an accident on a feeder of a DC power supply system in which a plurality of bases each including a power supply device are connected by the feeder, the estimation device including:
an information acquisition unit that acquires information from each base when the accident occurs; and
an estimation unit that estimates the position of occurrence of the accident in the feeder by comparing the information between the bases.

### Advantageous Effects of Invention

According to the disclosed technique, a position in a feeder where an accident has occurred can be estimated in a DC power supply system in which a plurality of bases are connected by the feeder.

### BRIEF DESCRIPTION OF DRAWINGS

FIG. 1 is a diagram showing an example of an overall configuration of a DC power supply system.

FIG. 2 is a diagram showing an example of a DC power supply system in one building.

FIG. 3 is a diagram showing an example of a DC power supply system in which bases are connected by an outdoor feeder.

FIG. 4 is a diagram for explaining an overview of an embodiment.

FIG. 5 is a diagram for explaining an overview of an embodiment.

FIG. 6 is a diagram showing a configuration example of an estimation device.

FIG. 7 is a flowchart for explaining an operation of the estimation device.

FIG. 8 is a diagram for explaining an example of calculation between two bases.

FIG. 9 is a diagram for explaining an example of calculation among three bases.

FIG. 10 is a diagram showing an example of a hardware configuration of a device.

### DESCRIPTION OF EMBODIMENTS

An embodiment of the present invention (present embodiment) will be described below with reference to the drawings. An embodiment which will be described below is merely an example, and embodiments to which the present invention is applied are not limited to the following embodiment.

In the embodiment described below, a short circuit is described as an example of an accident occurring in a feeder, but the technique according to the present invention can be applied to an accident other than a short circuit (for example, ground fault).

### (Example of Overall Configuration of System)

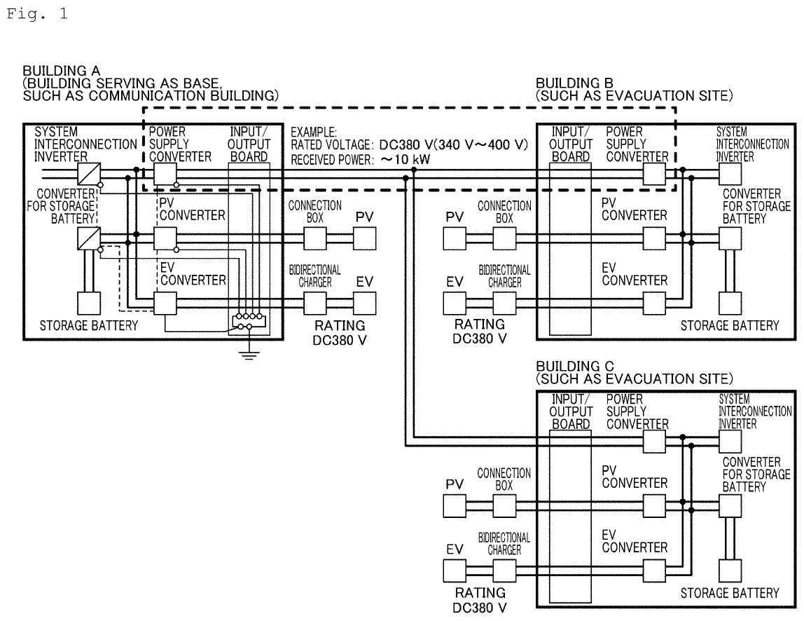

FIG. 1 shows an example of an overall configuration of a DC power supply system according to the present embodiment. In the DC power supply system shown in FIG. 1, power is supplied over a long distance (for example, approximately 4 km) at a high voltage (for example, 380 V) by an outdoor feeder.

In the example shown in FIG. 1, there are three bases, i.e., buildings A, B, and C, each of which is provided with a power supply converter and can supply power to other buildings. That is, it is possible to perform bidirectional power supply between any two of the three bases. In the example shown in FIG. 1, the building A is a building which is a base of a communication building or the like, and the buildings B and C are buildings such as evacuation sites, respectively. The power supply converter may be called a power supply device. However, the “power supply device” is not limited to a power supply converter.

As shown in FIG. 1, each base is provided with a power generation facility such as a photovoltaic generator (PV) and wind power generation, and a load such as an EV and a storage battery, power interchange can be performed bidirectionally between bases by the converter.

### (Problems)

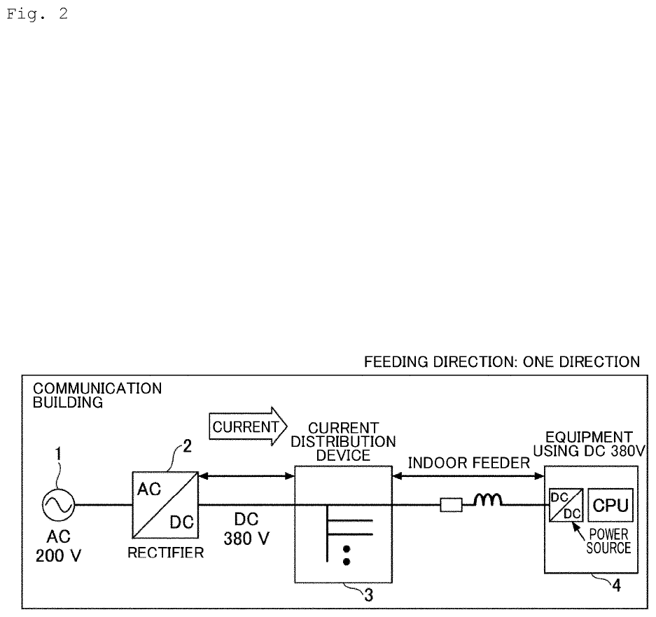

The problem to be solved by the technique according to the present invention will be described hereinafter in detail. For comparison, FIG. 2 shows an example of a conventional indoor (in a communication building) DC power supply system. As shown in FIG. 2, the DC power supply system includes an AC 200V1, a rectifier 2, a current distribution device 3, and a load 4 (DC 380 V utilization equipment).

As shown in FIG. 2, one-way power supply from the rectifier 2 to the load 4 is performed by a cable having a maximum of approximately 60 m in length. Therefore, the power to the load 4 such as an ICT device can be stably transmitted.

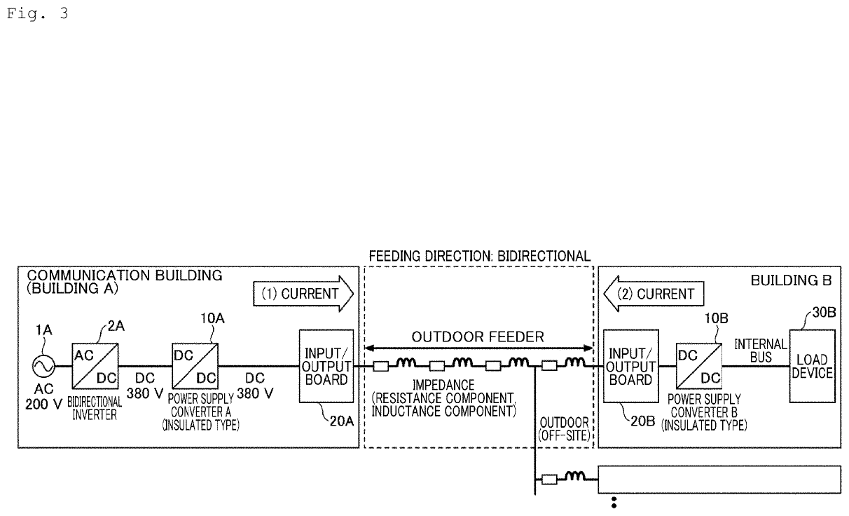

FIG. 3 shows a DC power supply system corresponding to a frame portion surrounded by a dotted line in FIG. 1. As shown in FIG. 3, the building A (communication building) is provided with a power supply 1A of the AC 200 V, a bidirectional inverter 2A, a power supply converter A(10A), and an input/output board 20A. The building B is provided with an input/output board 20B, a power supply converter 10B, and a load device 30B.

The building A and the building B are connected by an outdoor feeder capable of bidirectional feeding, and the length thereof is, for example, 4 km at a maximum.

In the case of supplying power over a long distance as in the configuration shown in FIG. 3, the impedance (resistance component, inductance component) becomes larger by approximately two digits than the impedance in the configuration shown in FIG. 2.

When a short circuit occurs in the feeder between the building A and the building B, the resistance of the feeder rapidly decreases, whereby a large current flows through the feeder. For this reason, there are cases where, for example, the fuse in the building might be melted and cut, and the cable might burn out at the short circuit point of the feeder.

In the case where power is supplied from a certain base to another base via an outdoor feeder as in the outdoor DC power supply system shown in FIG. 3, power might be supplied to a distant place located several km away, such as 4 km at a maximum. In this case, it is impossible to visually confirm where the short circuit point has occurred, disabling an operator from immediately rushing to an accident site. Such a problem may occur in the case of using a long feeder even in an indoor DC power supply system.

### (Example of System Configuration According to Embodiment)

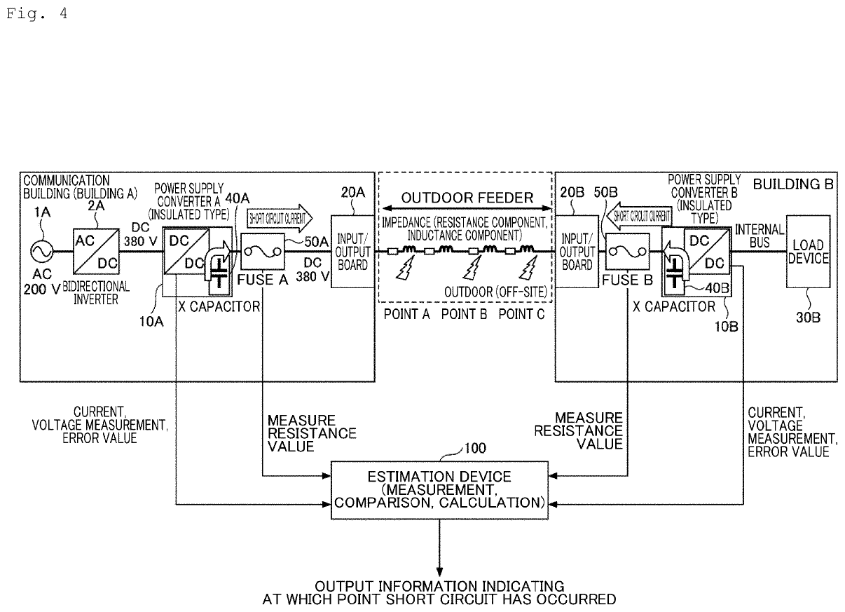

In order to solve the above problem, the present embodiment includes an estimation device 100 connected by a network (communication line) of a DC power supply system, as shown in FIG. 4.

FIG. 4 shows an example of a DC power supply system having two bases, i.e., the building A and the building B, as in the example shown in FIG. 3. Furthermore, in order to describe a flow of current that occurs when a short circuit occurs, FIG. 4 shows X capacitors 40A, 40B and fuses 50A, 50B.

The X capacitors are capacitors provided between a positive feeder and a negative feeder. The X capacitors are provided inside a power supply capacitor. The fuses are provided in a feeder between, for example, an output point (an output point on an outdoor feeder side) of the power supply capacitor and the input/output board 20. The fuses may be provided in the input/output board 20. The fuses normally have a small resistance, but melts and cuts off within a predetermined time once a large current flows and the resistance value increases and exceeds a certain current value. The relationship between the current value and the resistance value in the fuses is nonlinear, and the characteristics of the fuses vary by types of the fuses.

Protection from a short circuit is performed by a gate block (GB) provided in the power supply converter and the fuses. The GB of the power supply converter detects an overcurrent at the time of short circuit and stops the output of the power supply converter at approximately several us to several ms. However, even if the GB was able to stop the output within a short period of time, the electric charges accumulated in the X capacitors outside the GB (on the feeder side) becomes a large current and flows through the feeder, thereby possibly melting and cutting the fuses.

An example of an event that occurs will be described with reference to the configuration shown in FIG. 4. For example, when a short circuit occurs at a point C closer to the building B than the building A, the power supply converters 10A and 10B detect an overcurrent and immediately stop the output, but mainly the electric charges of the X capacitors 40A, 40B flow to the short circuit point.

At this time, since a current larger than a current flowing in the fuse 50A of the building A flows in the fuse 50B of the building B having a small impedance (short distance) between the fuse 50B and the short circuit point, a high resistance (several Ω) is obtained immediately before the fusion, and large current and large voltage are observed.

On the other hand, the fuse 50A of the building A having a large impedance (long distance) between the fuse 50A and the short circuit point is not melted/cut, and the resistance value remains, for example, 0 Ω, and both the current and voltage are smaller than those of the building B.

Based on such actions described above, the estimation device 100 estimates at which point the short circuit has occurred, based on information collected from each base.

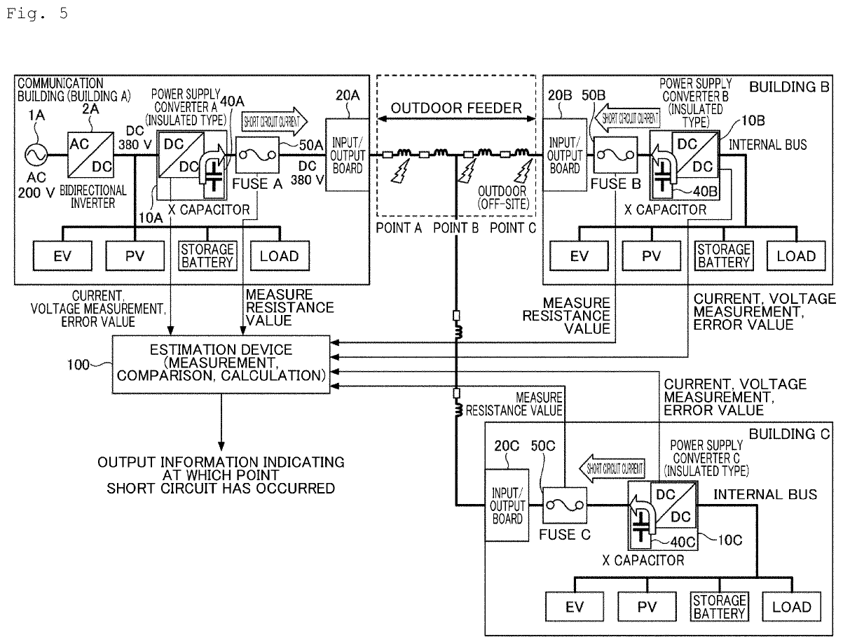

As shown in the example in FIG. 4, the number of bases in the DC power supply system is 2. There may be three or more bases. FIG. 5 shows an example of a configuration of a DC power supply system when the number of bases is three. In the case of the configuration shown in FIG. 5, the estimation device 100 collects information from the three bases, i.e., the building A, the building B, and the building C, and compares these pieces of information, to estimate a point where a short circuit occurs (at which point near the base of the feeder the short circuit occurs, etc.).

### (Configuration of Estimation Device 100)

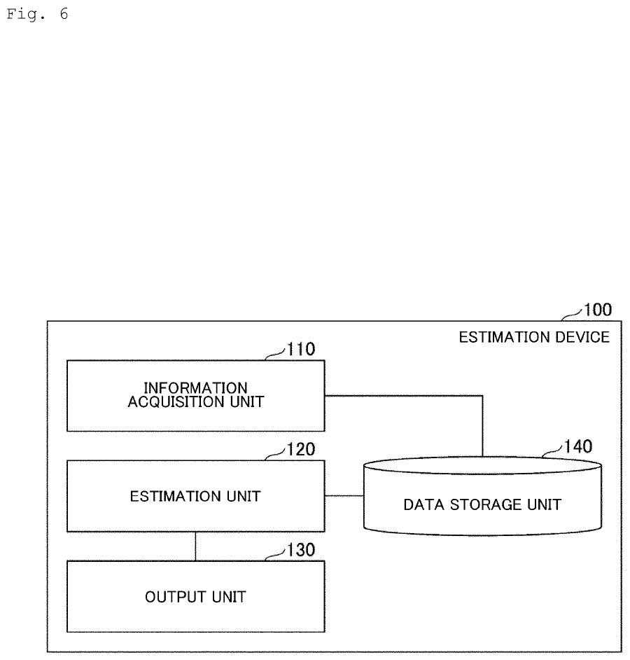

FIG. 6 shows a configuration example of the estimation device 100 according to the present embodiment. As shown in FIG. 6, the estimation device 100 includes an information acquisition unit 110, an estimation unit 120, an output unit 130, and a data storage unit 140. The outline of an operation of each unit is as follows.

The information acquisition unit 110 acquires information from each of the bases. When performing estimation based on the resistance value of the fuse, the information acquisition unit 110 acquires the resistance value of the fuse from each base. When performing estimation based on the current value, the information acquisition unit 110 acquires the current value from each base. These information acquisitions are performed in the wake of the detection of a short circuit. The information acquisition unit 110 acquires information based on a current flowing when a short circuit occurs.

The pieces of information described above are an example, and the information acquisition unit 110 may additionally acquire information other than the foregoing pieces of information.

The estimation unit 120 estimates the position (point) where a short circuit occurs, on the basis of the information acquired by the information acquisition unit 110 and the information stored in the data storage unit 140 (facility configuration including the geographical position of the feeder).

The output unit 130 outputs the estimation result obtained by the estimation unit 120. The output information may be, for example, an image in which a mark indicating the short circuit point and indicating a point on the path of the feeder is attached on a map containing an area where the feeder of the DC power supply system is attached, text information (for example, 1 km away from the building A) indicating the short circuit point, or information other than the above information. The output unit 130 may output information other than the estimation result together with the estimation result.

The output unit 130 may include a display, and display the output information on the display, or the output unit 130 may include a Web server and display the output information to a remote terminal via a network.

### (Example of Operation of Estimation Device 100)

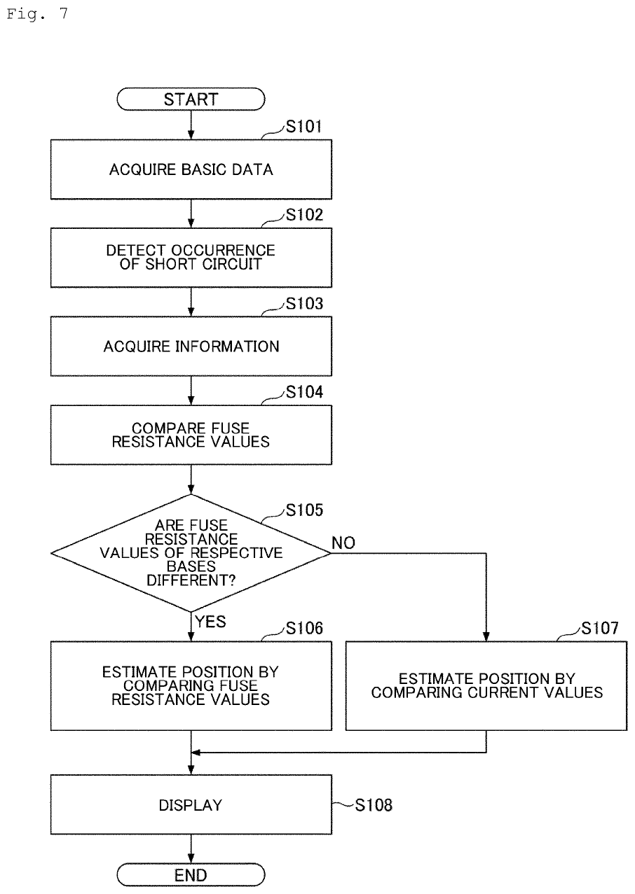

An example of an operation of the estimation device 100 will be described with reference to the procedure of the flowchart shown in FIG. 7. An example of a more specific operation method will be described after the description of the flow shown in FIG. 7.

In S101, basic data in the DC power supply system where a short circuit point is to be estimated is input to the estimation device 100, and the basic data is stored in the data storage unit 140.

Examples of the basic data include an X capacitor capacity, a cable impedance, fuse blowing characteristics, a power network configuration, a facility configuration, a specification of the power supply converter of each base, and the like.

By storing such data in the data storage unit 140, even if the information is not used for estimating the short circuit point, the operator can quickly confirm the information or the like that the operator desires to know when a short circuit occurs. Information other than the information used for estimation and outputting the short circuit point may not be input in S101.

In S102, for example, the information acquisition unit 110 in the estimation device 100 detects the occurrence of an accident (short circuit, in this case) in the DC power supply system. The detection of the occurrence of a short circuit may be executed by any method.

For example, the occurrence of a short circuit may be detected by the estimation device 100 receiving a signal indicating that the GB of the power supply converter 10 at any base has operated. Further, for example, the occurrence of a short circuit may be detected by the estimation device 100 receiving a signal indicating the occurrence of the short circuit, from a monitoring device for monitoring the DC power supply system.

In S103, the information acquisition unit 110 acquires information necessary for estimating the short circuit point, from each base. Examples of the information acquired here include a resistance value between both ends of the fuse from a time immediately before the occurrence of the short circuit to a certain time after the occurrence of the short circuit, and the current value of the feeder between the power supply converter and the input/output board. The resistance value and current value to be acquired may be a value at a certain time interval or a waveform in a continuous time lapse. In addition to the current value or instead of the current value, the amount of electricity may be acquired. The amount of electricity may be calculated from the acquired current value.

Information not used for automatic estimation of the short circuit point may be included in the acquired information. Examples of the acquired information includes, in addition to the resistance value and the current value, the PV power, the SoC of the storage battery, a load capacity, a converter error log, an output voltage value of the converter, and the like. By outputting these pieces of information from the output unit 130, the operator can grasp the converter error log or the like in addition to the automatic estimation result, and can confirm the accuracy or the like of the estimation result. The information acquired by the information acquisition unit 110 is stored in the data storage unit 140.

In S104, the estimation unit 120 compares, between the bases, the resistance values of the fuses acquired from the respective bases.

In S105, the estimation unit 120 determines whether or not the resistance value of a fuse differs between the bases. The difference in resistance value of a fuse between the bases means that when there are three or more bases, there is at least one base having a resistance value different from the other bases. The “different resistance value” may be, for example, |R1−R2|>= threshold when R1 and R2 exist. In other words, the minute differences may be regarded as the same.

If the determination in S105 is Yes (resistance value is different between bases), the processing proceeds to S106, and if the determination in S105 is No (resistance value is the same between bases), the processing proceeds to S107.

In S106, the estimation unit 120 estimates the position where a short circuit occurs, on the basis of comparison between the fuse resistance values of the bases. In S107, the estimation unit 120 estimates the position where a short circuit occurs, on the basis of the comparison between the current values (or the amounts of electricity) of the bases. A specific example of S106, S107 will be described below.

In S108, the output unit 130 displays the short circuit point on the path of the feeder in the DC power supply system. In S108, the information (e.g., an error value of the converter) acquired in S103 and not used for estimation may be additionally displayed. The position of the short circuit point on the path of the feeder displayed in S108 indicates an approximate position.

In the example of the flow described above, both the resistance value of the fuse and the current value (or the amount of electricity) are used, but this is an example. The estimation may be performed by using only the resistance value of the fuse, or the estimation may be performed by using only the current value (or the amount of electricity). Further, the position of occurrence of the short circuit may be estimated from information other than the resistance value, the current value, and the amount of electricity.

### SPECIFIC EXAMPLE

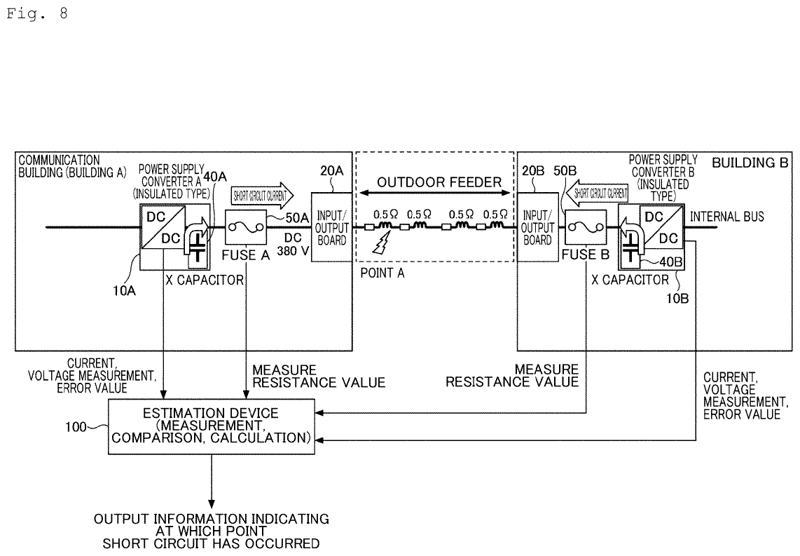

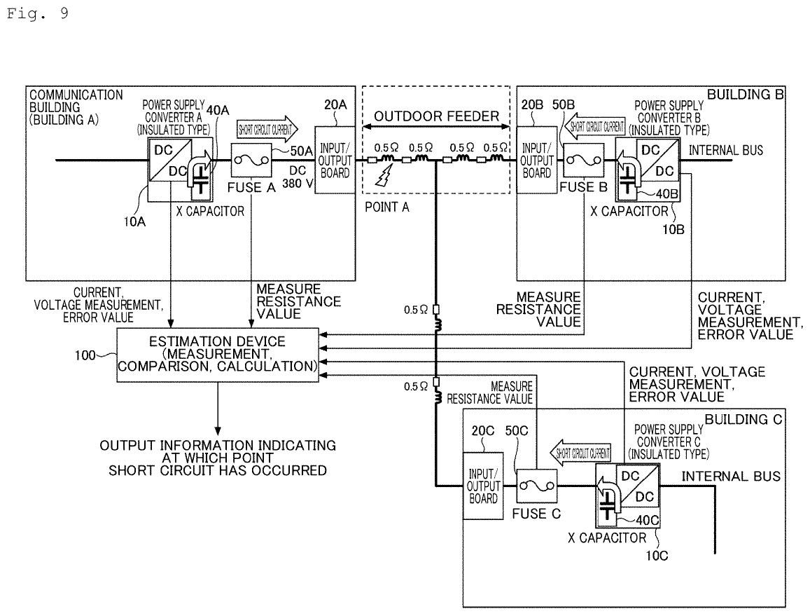

A specific example of the estimation of the position of a short circuit will be described with reference to FIG. 8 and FIG. 9. Here, it is assumed that the fuses at the respective bases are the same at the respective bases. The description will be made with reference to FIG. 8 first. FIG. 8 shows a DC power supply system having two bases, as in FIG. 4.

<Case with Two Bases: Estimation by Resistance Value>

It is assumed that after a short circuit occurs, the information acquisition unit 110 acquires 3 Ω as the resistance value of the fuse 50A of the building A and 1 Ω as the resistance value of the fuse 50B of the building B. These resistance values may be the maximum resistance value in the time period in which the short circuit has occurred (time period from immediately before the occurrence to a certain time after the occurrence), or may be the resistance value (a value which can be estimated to be the maximum value described above) measured at the time of the occurrence of the short circuit (for example, immediately after the occurrence of the short circuit is detected).

It can be estimated that the larger the resistance value of the fuse, the larger the current that flows through the fuse. The fact that a large current flows means that the distance (impedance) between the short circuit point and the building having the fuse is short.

Therefore, the estimation unit 120 estimates that the larger the resistance value, the closer the position of the short circuit is to the building where the resistance value is measured.

For example, as shown in FIG. 4, in accordance with the distance between the building A and the building B, a point A (a point close to the building A), a point B (a point close to the middle between the building A and the building B), and a point C (a point close to the building B) are determined in advance.

Since the resistance value of the fuse 50A is 3 Ω and the resistance value of the fuse 50B of the building B is 1 Ω, the estimation unit 120 estimates that a short circuit occurs at the point A.

In addition to the above-mentioned relationship between the resistance values (or instead of the above-mentioned relationship between the resistance values), the position may be estimated using the sizes of resistance values (amounts of changes) and information on whether or not a fuse has melted/cut. Note that whether a fuse has melted/cut or not is determined when the resistance value is extremely large (when the resistance value is infinite or larger than a threshold).

For example, when the resistance value at a certain base does not change due to the occurrence of a short circuit, the estimation unit 120 estimates that the short circuit occurrence point is far from the base (that is, near the opposite base).

When the resistance value at a certain base becomes larger than normal due to the occurrence of a short circuit, the estimation unit 120 determines the short circuit occurrence point by comparing the resistance value of the short circuit occurrence point with the resistance value of the other base.

When it is determined that the fuse at a certain base has melted/cut, the estimation unit 120 determines that the short circuit occurrence point is close to said base. For example, when the fuse 50A of the building A has melted/cut, the estimation unit 120 can estimate that the short circuit occurrence point is the base A shown in FIG. 8.

<Case with Two Bases: Estimation by Current Value (or Amount of Electricity)>

It is assumed that the information acquisition unit 110 acquires 300 A as the current value of the building A and 100 A as the current value of the building B after the occurrence of a short circuit. These current values may be the maximum value (peak value) of the current value during the time period in which the short circuit has occurred (the time period from immediately before the occurrence to a certain time after the occurrence), or may be the current value (a value which can be estimated to be the maximum value described above) measured at the occurrence of the short circuit (e.g., immediately after the occurrence of the short circuit).

Further, the current values may be any measured value of the feeder between the power supply converter 10 and the input/output board 20, or, for example, the output current value of the power supply converter 10.

The large current value at a certain base means that the distance (impedance) between the short circuit point and the base is small.

Therefore, the estimation unit 120 estimates that the larger the current value, the closer the position of the short circuit point is to the building where the current value is measured. The position of the short circuit point may be estimated roughly by using a predetermined point or the like, as in the case of the resistance value, or may be calculated as follows.

Here, it is assumed that the current value measured in the building A is I_{A}, and that the current value measured in the building B is I_{B}. The length of the feeder between the building A and the building B is defined as L, the distance from the building A to the position of the short circuit point (distance along the feeder) is defined as DA, and the distance from the building B to the position of the short circuit point (distance along the feeder) is defined as DB.

The estimation unit 120 calculates DA and DB as “1/I_{A}:1/I_{B}=DA:DB”. Specifically, the calculation can be performed such as DA=(L×I_{B})/(I_{A}+I_{B}), DB=(L×I_{A})/(I_{A}+I_{B}).

For example, when L=4 km, I_{A}=300A, and I_{B}=100A, the calculation can be performed with DA=1 km and DB=3 km.

In the above example, the beak current value is used, but the amount of electricity during the time period in which the short circuit has occurred (time period from immediately before the occurrence to a certain time after the occurrence) may be used. The amount of electricity can be obtained by integrating the waveform of the acquired current value with time.

The estimation of the position of the short circuit point in the case of using the amount of electricity is the same as in the case of using the current value. For example, assuming that the amount of electricity measured in the building A is defined as C_{A} and the amount of electricity measured in the building B is defined as C_{B}, the estimation unit 120 calculate DA and DB on the basis of the relationship of “1/C_{A}:1/C_{B}=DA:DB”.

<Case with Three Bases: Estimation by Resistance Value>

Description will be made with reference to FIG. 9. FIG. 9 shows a DC power supply system having three bases, as in FIG. 5.

It is assumed that after a short circuit occurs, the information acquisition unit 110 acquires 3 Ω as the resistance value of the fuse 50A of the building A, 1 Ω as the resistance value of the fuse 50B of the building B, and 1 Ω as the resistance value of the fuse 50C of the building C. These resistance values may be the maximum resistance value in the time period in which the short circuit has occurred (time period from immediately before the occurrence to a certain time after the occurrence), or may be the resistance value (a value which can be estimated to be the maximum value described above) measured at the time of the occurrence of the short circuit (for example, immediately after the occurrence of the short circuit is detected).

It can be estimated that the larger the resistance value of the fuse, the larger the current that flows through the fuse. The fact that a large current flows means that the distance (impedance) between the short circuit point and the building having the fuse is short.

Therefore, the estimation unit 120 estimates that the larger the resistance value, the closer the position of the short circuit is to the building where the resistance value is measured.

For example, as shown in FIG. 5, in accordance with the distance between the building A and the building B, a point A (a point close to the building A), a point B (a point close to the middle between the building A and the building B), and a point C (a point close to the building B) are determined in advance. Similarly, for the feeder between the building C and the connection point between the feeder between the building A and the building B and the feeder extending from the building C, for example, points E, F, and the like may be determined in advance in accordance with the distance from the building C.

The estimation unit 120 estimates that a short circuit occurs at the point A since the resistance value of the fuse 50A of the building A is 3 Ω, the resistance value of the fuse 50B of the building B is 1 Ω, and the resistance value of the fuse 50C of the building C is 1 Ω.

In addition to the above-mentioned relationship between the resistance values (or instead of the above-mentioned relationship between the resistance values), the position may be estimated using the sizes of resistance values (amounts of changes) and information on whether or not a fuse has melted/cut. Note that whether a fuse has melted/cut or not is determined when the resistance value is extremely large (when the resistance value is infinite or larger than a threshold).

For example, when the resistance value at a certain base does not change due to the occurrence of a short circuit, the estimation unit 120 estimates that the short circuit occurrence point is far from the base (that is, near a base other than said base).

When the resistance value at a certain base becomes larger than normal due to the occurrence of a short circuit, the estimation unit 120 determines the short circuit occurrence point by comparing the resistance value of the short circuit occurrence point with the resistance value of the other base.

When it is determined that the fuse at a certain base has melted/cut, the estimation unit 120 determines that the short circuit occurrence point is close to said base. For example, when the fuse 50A of the building A has melted/cut, the estimation unit 120 can estimate that the short circuit occurrence point is the base A shown in FIG. 9.

<Case with Three Bases: Estimation by Current Value (or Amount of Electricity)>

It is assumed that the information acquisition unit 110 acquires 300 A as the current value of the building A, 100 A as the current value of the building B, and 100 A as the current value of the building C after the occurrence of the short circuit. These current values may be the maximum value (peak value) of the current value during the time period in which the short circuit has occurred (the time period from immediately before the occurrence to a certain time after the occurrence), or may be the current value (a value which can be estimated to be the maximum value described above) measured at the occurrence of the short circuit (e.g., immediately after the occurrence of the short circuit).

Further, the current values may be any measured value of the feeder between the power supply converter 10 and the input/output board 20, or, for example, the output current value of the power supply converter 10.

The large current value at a certain base means that the distance (impedance) between the short circuit point and the base is small.

Therefore, the estimation unit 120 estimates that the larger the current value, the closer the position of the short circuit point is to the building where the current value is measured. The position of the short circuit point may be estimated roughly by using a predetermined point or the like, as in the case of the resistance value, or may be calculated as follows.

Here, it is assumed that the current value measured in the building A is I_{A}, the current value measured in the building B is I_{B}, and the current value measured in the building C is I_{C}. The distance from the building A to the position of the short circuit point (distance along the feeder) is defined as DA, the distance from the building B to the position of the short circuit point (distance along the feeder) is defined as DB, and the distance from the building C to the position of the short circuit point (distance along the feeder) is defined as DC.

The estimation unit 120 calculates DA, DB and DC as “1/I_{A}:1/I_{B}:1/I_{C}=DA:DB:DC”. Specifically, for example, a certain length L (e.g., the sum of the lengths of feeders connecting bases, which in this case is 7 km, for example) is determined, and the 7 km is distributed by “1/I_{A}:1/I_{B}:1/I_{C}”. When L=7 km, DA: DB: DC=1 km:3 km:3 km. For example, the estimation unit 120 pays attention to DA whose distance becomes the shortest, and estimates that a short circuit occurs at a point 1 km away from the building A. Since the current value is the maximum, it may be estimated that the short circuit has occurred at a point 1 km away from the building A, by paying attention to DA, that is, the building A.

In the above example, the beak current value is used, but the amount of electricity during the time period in which the short circuit has occurred (time period from immediately before the occurrence to a certain time after the occurrence) may be used. The amount of electricity can be obtained by integrating the waveform of the acquired current value with time.

The estimation of the position of the short circuit point in the case of using the amount of electricity is the same as in the case of using the current value. For example, when the amount of electricity measured in the building A is defined as C_{A}, the amount of electricity measured in the building B is defined as C_{B}, and the amount of electricity measured in the building C is defined as C_{C}, the estimation unit 120 can calculate DA, DB, and DC based on the relationship of “1/C_{A}:1/CB:1/C_{C}=DA:DB:DC”.

### (Example of Hardware Configuration of Device)

The estimation device 100 can be realized, for example, by causing a computer to execute a program. The computer may be a physical computer or a virtual machine on a cloud.

That is, the estimation device 100 can be realized by executing a program corresponding to processing performed by the estimation device 100 by using hardware resources such as a CPU and a memory built in the computer. The foregoing program can be recorded on a computer-readable recording medium (a portable memory or the like) to be stored or distributed. The foregoing program can also be provided through a network such as the Internet or e-mail.

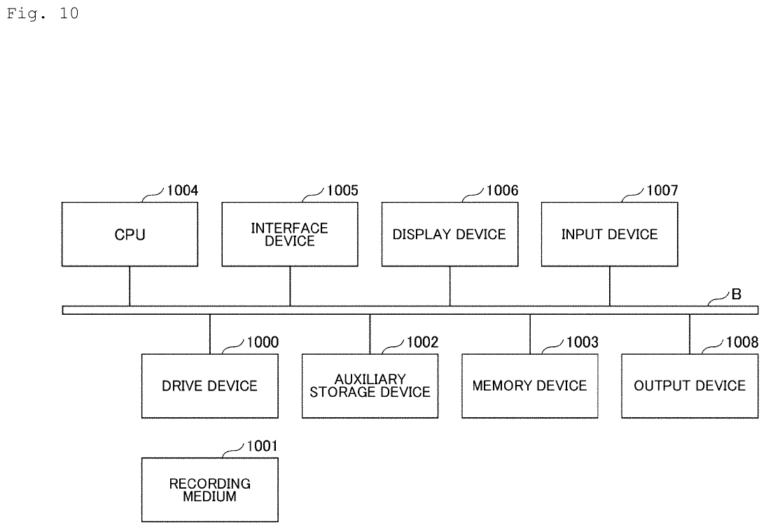

FIG. 10 is a diagram showing an example of a hardware configuration of the computer described above. The computer shown in FIG. 10 includes a drive device 1000, an auxiliary storage device 1002, a memory device 1003, a CPU 1004, an interface device 1005, a display device 1006, an input device 1007, an output device 1008, and the like which are connected to one another via a bus BS.

A program for realizing processing in the computer is provided by, for example, a recording medium 1001 such as a CD-ROM or a memory card. When the recording medium 1001 having the program stored therein is set in the drive device 1000, the program is installed on the auxiliary storage device 1002 from the recording medium 1001 via the drive device 1000. However, the program need not necessarily be installed from the recording medium 1001 and may be downloaded from another computer via a network. The auxiliary storage device 1002 stores the installed program and also stores necessary files, data, and the like.

The memory device 1003 reads and stores the program from the auxiliary storage device 1002 when provided with an instruction to start the program. The CPU 1004 realizes functions related to the estimation device 100 according to a program stored in the memory device 1003. The interface device 1005 is used as an interface for connection to a network, various measurement devices, and the like. The display device 1006 displays a GUI (Graphical User Interface) or the like according to a program. The input device 1007 is configured of a keyboard, a mouse, buttons, a touch panel, or the like, and is used to input various operation instructions. The output device 1008 outputs a calculation result.

### (Effects of Embodiments)

According to the technique according to the present embodiment, in a DC power supply system in which a plurality of bases are connected by a feeder, it is possible to estimate a location in the feeder where an accident occurs. Thus, the operator can quickly rush to the accident site and perform the restoration work.

### (Additional Notes)

The present specification discloses, at least, an estimation device, an estimation method, and a program described in each of the following clauses.

### (Clause 1)

An estimation device for estimating a position of occurrence of an accident on a feeder in a DC power supply system in which a plurality of bases each having a power supply device are connected by the feeder, the estimation device comprising:
a memory; and
at least one processor connected to the memory, wherein the processor includes:
an information acquisition unit that acquires information from each base when the accident occurs; and
an estimation unit that estimates the position of occurrence of the accident in the feeder by comparing the information between the bases.

### (Clause 2)

The estimation device according to clause 1, wherein the information is a resistance value of a fuse provided in a feeder in a base, a current value flowing in the feeder in the base, or an amount of electricity flowing in the feeder in the base.

### (Clause 3)

The estimation device according to clause 2, wherein the processor estimates a distance along a feeder between a base and the position of occurrence of the accident on the basis of a ratio between reciprocals of the current values or the amounts of electricity of the bases.

### (Clause 4)

The estimation device according to clause 2, wherein the processor estimates that the larger the resistance value, the current value, or the amount of electricity is at a certain base, the closer the position of the accident is to said base.

### (Clause 5)

The estimation device according to clause 1, wherein the processor displays the position of occurrence of the accident on a path of the feeder.

### (Clause 6)

An estimation method that is executed by a computer used as an estimation device for estimating a position of occurrence of an accident on a feeder in a DC power supply system in which a plurality of bases each having a power supply device are connected by the feeder, the estimation method comprising:
an information acquisition step of acquiring information from each base when the accident occurs; and
an estimation step of estimating the position of occurrence of the accident in the feeder by comparing the information between the bases.

### (Clause 7)

A non-transitory storage medium storing a program for causing a computer to function as the estimation device according to any one of clauses 1 to 5.

Although the embodiments have been described above, the present invention is not limited to the specific embodiments, and various modifications and changes can be made within the scope of the gist of the present invention described in the claims.

### REFERENCE SIGNS LIST

100 Estimation device

110 Information acquisition unit

120 Estimation unit

130 Output unit

140 Data storage unit

1000 Drive device

1001 Recording medium

1002 Auxiliary storage device

1003 Memory device

1004 CPU

1005 Interface device

1006 Display device

1007 Input device

1008 Output device

1. An estimation device for estimating a position of occurrence of an accident on a feeder in a DC power supply system in which a plurality of bases each having a power supply device are connected by the feeder, the estimation device comprising:
a processor; and
a memory storing program instructions that cause the processor to:
acquire information from each base when the accident occurs; and
estimate the position of occurrence of the accident in the feeder by comparing the information between the bases.

2. The estimation device according to claim 1, wherein the information is a resistance value of a fuse provided in a feeder in a base, a current value flowing in the feeder in the base, or an amount of electricity flowing in the feeder in the base.

3. The estimation device according to claim 2, wherein the program instructions cause the processor to estimate a distance along a feeder between a base and the position of occurrence of the accident on the basis of a ratio between reciprocals of the current values or the amounts of electricity of the bases.

4. The estimation device according to claim 2, wherein the program instructions cause the processor to estimate that the larger the resistance value, the current value, or the amount of electricity is at a certain base, the closer the position of the accident is to said base.

5. The estimation device according to claim 1, the program instructions cause the processor to display the position of occurrence of the accident on a path of the feeder.

6. An estimation method that is executed by an estimation device for estimating a position of occurrence of an accident on a feeder in a DC power supply system in which a plurality of bases each having a power supply device are connected by the feeder, the estimation method comprising:
acquiring information from each base when the accident occurs; and
estimating the position of occurrence of the accident in the feeder by comparing the information between the bases.

7. A non-transitory computer-readable recording medium having stored therein a program for causing a computer to perform the estimation method according to claim 6.
